(19) United States
(12) Patent Application Publication
(10) Pub. No.: US 2021/0383784 A1
(43) Pub. Date: Dec. 9, 2021

(54) BLANKING PANELS INCLUDING ACOUSTIC ABSORBING MATERIALS

(71) Applicant: 3M INNOVATIVE PROPERTIES COMPANY, St. Paul, MN (US)

(72) Inventors: Catherine A. Leatherdale, Woodbury, MN (US); James Michael Jonza, Lake Elmo, MN (US); Ronald Wayne Gerdes, St. Paul, MN (US); Thomas Herdtle, Inver Grove Heights, MN (US)

(21) Appl. No.: 17/284,896

(22) PCT Filed: Nov. 5, 2019
(86) PCT No.: PCT/IB2019/059504

§ 371 Date: Apr. 13, 2021

Related U.S. Application Data
(60) Provisional application No. 62/758,232, filed on Nov. 9, 2018.

(51) Int. Cl. G10K 11/168; H05K 7/14

(52) U.S. Cl. CPC G10K 11/168; H05K 7/1488

(57) ABSTRACT

An acoustic-absorbing blanking panel for an electronics rack includes a sheet of acoustic-absorbing material mounted or mountable onto a front panel, the front panel being mountable onto an electronics rack. The blanking panel exhibits an absorption band at a frequency between 800 Hz and 12000 Hz. The sheet of acoustic-absorbing material may be mounted onto a frame, the frame being mountable onto a server rack. The sheet of acoustic-absorbing material may include acoustic-absorbing film, non-woven material, foam, or a panel with a core having a honeycomb structure. An electronics server rack includes a rack with mounting rails, constructed to house electronics components. An acoustic-absorbing blanking panel is mounted on the mounting rails. The blanking panel includes a sheet of acoustic-absorbing material mounted onto a front panel, the front panel being mounted onto the rack. The blanking panel has an absorption band at a frequency between 800 Hz and 12000 Hz.

### FIELD

The present disclosure relates to blanking panels used in electronic equipment racks. In particular, the present disclosure relates to blanking panels that include acoustic absorbing materials.

### BACKGROUND

Electronic equipment, such as servers, networking equipment, power supplies, and other electronic equipment may be housed in equipment racks, also sometimes called server racks. Equipment racks typically have a frame and mounting flanges or rails for mounting electronic equipment onto the rack. The racks typically include a plurality of positions for housing a number of pieces of equipment (e.g., servers). For various reasons, however, the racks are often not fully configured with rack-mounted components, and may include vacant sections or mounting positions. Such vacant sections may be blocked or filled in by blanking panels.

Server rooms, and in particular server rooms with multiple servers mounted on server racks can be noisy due to the operation of cooling fans.

It would be desirable to provide a blanking panel that includes acoustic absorbing material to absorb sound associated with electronic equipment and cooling fans used to cool the equipment. It would further be desirable to provide an acoustic absorbing blanking panel that accommodates the needs, such as sound absorption frequency, sound reduction, rigidity, weight, thickness, air flow, fire resistance, etc., of panels used with computers, servers, or server racks.

### SUMMARY

An acoustic-absorbing blanking panel for an electronics rack includes a sheet of acoustic-absorbing material mounted or mountable onto a front panel, the front panel being mountable onto an electronics rack. The blanking panel exhibits an absorption band at a frequency between 800 Hz and 12000 Hz. The sheet of acoustic-absorbing material may be mounted onto a frame, the frame being mountable onto a server rack.

The sheet of acoustic-absorbing material may include an acoustic-absorbing film, such as a polymeric microperforated film. The sheet of acoustic-absorbing material may include non-woven material, foam, or a panel with a core having a honeycomb structure.

An electronics server rack includes a rack with mounting rails, constructed to house electronics components. An acoustic-absorbing blanking panel is mounted on the mounting rails. The blanking panel includes a sheet of acoustic-absorbing material mounted onto a front panel, the front panel being mounted onto the rack. The blanking panel has an absorption band at a frequency between 800 Hz and 12000 Hz.

### BRIEF DESCRIPTION OF FIGURES

FIG. 1A is a perspective view of an exemplary electronics server rack with sound-absorbing blanking panels according to an embodiment.

FIG. 1B is an exploded view of the electronics server rack of FIG. 1A.

FIG. 2 is a schematic perspective view of a sound-absorbing blanking panel according to an embodiment.

FIG. 3A is a schematic perspective view of a sound-absorbing blanking panel according to an embodiment.

FIG. 3B is a schematic front view of the sound-absorbing blanking panel of FIG. 3A.

FIG. 3C is a schematic top view of the sound-absorbing blanking panel of FIG. 3A.

FIG. 3D is a schematic bottom view of the sound-absorbing blanking panel of FIG. 3A.

FIG. 4 is a schematic perspective view of a sound-absorbing blanking panel according to an embodiment.

FIGS. 5A and 5B are schematic cross-sectional detail views of a sound-absorbing film of a sound-absorbing blanking panel according to embodiments.

FIG. 6A is a schematic perspective view of a sound-absorbing blanking panel according to an embodiment.

FIG. 6B is an exploded view of the sound-absorbing blanking panel of FIG. 6A.

FIG. 7A is a partial cross sectional top view of a sheet of sound-absorbing material used in a sound-absorbing blanking panel according to an embodiment.

FIG. 7B is a cross-sectional view of the exemplary panel of FIG. 7A.

FIG. 7C is a perspective view of a cell of the sound-absorbing material of FIG. 7A.

FIG. 8 is a schematic of a sound-absorbing panel used in the Examples.

FIG. 9 is a schematic of a sound-absorbing panel used in the Examples.

FIGS. 10A and 10B are schematic views of the test set-ups used in the Examples.

### DETAILED DESCRIPTION

The present disclosure relates to acoustic sound-absorbing panels. In particular, the present disclosure relates to acoustic sound-absorbing panels adapted for use with computers, servers, and server racks.

The terms “integral” and “integrally formed” are used in this disclosure to describe elements that are formed in one piece (a single, unitary piece) and cannot be separably removed from each other without causing structural damage to the piece.

The term “interconnected” is used here to refer to spaces (e.g., internal portions of cells) that are in fluid communication with one another.

The terms “flame retardant,” “flame resistant,” and “fire resistant” are used to refer to characteristics of materials that slow down ignition and flame propagation relative to other materials.

Relative terms such as proximal, distal, left, right, forward, rearward, top, bottom, side, upper, lower, horizontal, vertical, and the like may be used in this disclosure to simplify the description. However, such relative terms do not to limit the scope of the invention in any way. Terms such as left, right, forward, rearward, top, bottom, side, upper, lower, horizontal, vertical, and the like are from the perspective observed in the particular figure.

The term “substantially” as used here has the same meaning as “significantly,” and can be understood to modify the term that follows by at least about 75%, at least about 90%, at least about 95%, or at least about 98%. The term “not substantially” as used here has the same meaning as “not significantly,” and can be understood to have the inverse meaning of “substantially,” i.e., modifying the term that follows by not more than 25%, not more than 10%, not more than 5%, or not more than 2%.

The term “about” is used here in conjunction with numeric values to include normal variations in measurements as expected by persons skilled in the art, and is understood have the same meaning as “approximately” and to cover a typical margin of error, such as ±5% of the stated value.

Terms such as “a,” “an,” and “the” are not intended to refer to only a singular entity, but include the general class of which a specific example may be used for illustration.

The terms “a,” “an,” and “the” are used interchangeably with the term “at least one.” The phrases “at least one of” and “comprises at least one of” followed by a list refers to any one of the items in the list and any combination of two or more items in the list.

As used here, the term “or” is generally employed in its usual sense including “and/or” unless the content clearly dictates otherwise. The term “and/or” means one or all of the listed elements or a combination of any two or more of the listed elements.

The recitations of numerical ranges by endpoints include all numbers subsumed within that range (e.g., 1 to 5 includes 1, 1.5, 2, 2.75, 3, 3.80, 4, 5, etc. or 10 or less includes 10, 9.4, 7.6, 5, 4.3, 2.9, 1.62, 0.3, etc.). Where a range of values is “up to” or “at least” a particular value, that value is included within the range.

The words “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure, including the claims.

Server rooms, and in particular server rooms with multiple servers mounted on server racks can be noisy due to the operation of cooling fans. However, it has been found that hard disk drives are sensitive to high frequency sound. A recent study by T. Dutta (Master's Thesis, Michigan Technological University, December 2017) showed that the performance of hard disk drives from multiple manufacturers can be adversely affected by sound levels above 90 dB. Certain sound frequencies correspond to the modal frequencies of the platters of the hard disk drives. Such frequencies occur around 1100 Hz, 1800 Hz, 3100 Hz, 4600 Hz, 6350 Hz, and 7900 Hz. Loud sounds at or around these frequencies may negatively affect hard disk drive performance. Others have shown that selective excitation of the hard disk drive platter modal frequencies could result in hard disk drive failure and could be exploited for a denial of service attack for example (M. Shahrad et al., Acoustic Denial of Service Attacks on Hard Disk Drives, 2018 Workshop on Attacks and Solutions in Hardware Security (ASHES 2018), Toronto, Canada). Systems used to cool computers or servers may create noise at or around the frequencies that may negatively impact hard disk drive performance. The sound level above which performance begins to be adversely affected varies and may depend on the individual hard disk drives. Other components in or attached to the electronic equipment may also be adversely affected by airborne vibrations or noise.

Sound-absorbing panels are sometimes used to reduce sound in various structures, including buildings and vehicles. Such panels are typically provided with qualities specific to the intended use. For example, the sound-absorbing panels may be adapted to have specific sound reduction level, sound absorption frequency, and other properties that facilitate their use in buildings or vehicles. Sound-absorbing panels are typically adapted to increase the comfort of humans in those environments, reducing sound levels and frequencies that are relevant to humans.

There exists a need for panels that are suitable for use with computers, servers, and server racks. It would be desirable to provide an acoustic absorbing panel with features that accommodate computers, servers, and server racks, such as sound absorption frequency, sound reduction, rigidity, weight, thickness, air flow, fire resistance, etc. It would further be desirable to provide an acoustic absorbing panel that can also serve as a blanking panel for an electronic equipment rack (e.g., server rack).

Electronic equipment racks come in two standard widths, 19 inches and 23 inches. Equipment is mounted onto vertical mounting flanges or rails that extend from the bottom 14 of the rack to the top 15 of the rack. The rails have holes vertically spaced apart to accommodate attachment of equipment by screws, nuts and bolts, or other attachment mechanisms. Equipment for racks typically has a height that is a multiple of a rack unit, abbreviated as “U”. The height of one rack unit (e.g., U) is 1.75 inches (44.5 mm). Equipment for racks may have a height of, for example, 1U, 2U, 3U, or 4U. The front panels of equipment or blanking panels may be slightly shorter than 1U (or slightly shorter than a multiple of U) to allow for some clearance between adjacent mounted components.

One way of reducing the effects of loud sounds is adding heavy panels to a structure to reflect or absorb sound energy. However, simply adding mass to individual enclosures or the electronics rack to reflect the sound energy is not desirable. Electronics server racks may be limited in their capacity based on floor weight limitations (typically less than 3500 lbs. for the full rack), and adding heavy metal panels to reduce sound could limit the overall density of electronic equipment in a data center. Therefore, light weight electronic enclosures are desirable. Further, lightweight electronic enclosures may enable one-person serviceability.

The sound-absorbing blanking panels of the present disclosure may conveniently be used to both block vacant slots in an electronics rack and also to absorb sound, which may improve the performance of equipment (e.g., servers) mounted onto the rack. The sound-absorbing blanking panels exhibit sound absorption at specific frequencies, sound reduction, rigidity, weight, thickness, air flow resistance, heat resistance, fire resistance, etc., suitable for use with computers, servers, and server racks. The sound-absorbing blanking panels of the present disclosure may be constructed to have any suitable size (e.g., a height of a single unit (1U) or several units), they may be light weight, rigid, and/or may be made of recyclable materials.

According to an embodiment, the sound-absorbing blanking panel includes a sheet of sound-absorbing material mounted or mountable onto a front panel. The front panel may be mounted onto the electronics rack. Alternatively, the sheet of sound-absorbing material may be mounted directly onto the electronics rack, and a front panel may be mounted separately onto the rack in front of the sheet of sound-absorbing material, or may be mounted onto the sheet of acoustic-absorbing material. The sheet of sound-absorbing material may optionally be supported by a frame.

The sound-absorbing blanking panel 100 may include one or more sheets of sound-absorbing material. Exemplary materials that can be used as the sheet of sound-absorbing material include sound-absorbing film, foam, non-woven material, woven material, and layered multi-cell material.

According to some embodiments, the sound-absorbing blanking panel includes a frame mountable on an electronics rack, a cavity at least partially defined by the frame, and a sheet of acoustic-absorbing material. The cavity is disposed adjacent the sheet of acoustic-absorbing material such that the sheet of acoustic-absorbing material at least partially forms a wall surrounding the cavity. The sound-absorbing blanking panel may include more than one sheet of acoustic-absorbing material and/or more than one sound-absorbing material. The frame may include a front panel or may be couplable with a front panel.

In some embodiments, the sound-absorbing blanking panel includes a frame, and the sheet of acoustic-absorbing material substantially covers at least one side of the frame, such as a top, a bottom, a front, a back, and/or a side. In some embodiments, the frame has at least one open side (i.e., a side that lacks a panel), such as a top, a bottom, a front, a back, and/or a side.

The sound-absorbing blanking panel may include mounting elements capable of tool-less mounting onto the electronics rack or onto equipment on the electronics rack (e.g., non-sound absorbing blanking panels). For example, the sound-absorbing blanking panel may include mounting elements on the sheet of acoustic-absorbing material, on the frame, and/or on the front panel.

The sound-absorbing blanking panel may be capable of absorbing sounds at a broad frequency range. Preferably, the sound-absorbing blanking panel is capable of absorbing sounds at a frequency range that includes frequencies that may cause problems with computer hard drives. According to an embodiment, the sound-absorbing blanking panel is constructed to absorb sounds at least at an acoustical frequency of 300 Hz or above, 500 Hz or above, 800 Hz or above, 1000 Hz or above, 1400 Hz or above, 1600 Hz or above, 1800 Hz or above, 1900 Hz or above, 2000 Hz or above, or 2100 Hz or above. The sound-absorbing panel may be constructed to absorb sounds at least at an acoustical frequency of 12000 Hz or lower, 10000 Hz or lower, 8000 Hz or lower, 6000 Hz or lower, 4000 Hz or lower, 3500 Hz or lower, 3000 Hz or lower, 2800 Hz or lower, or 2500 Hz or lower.

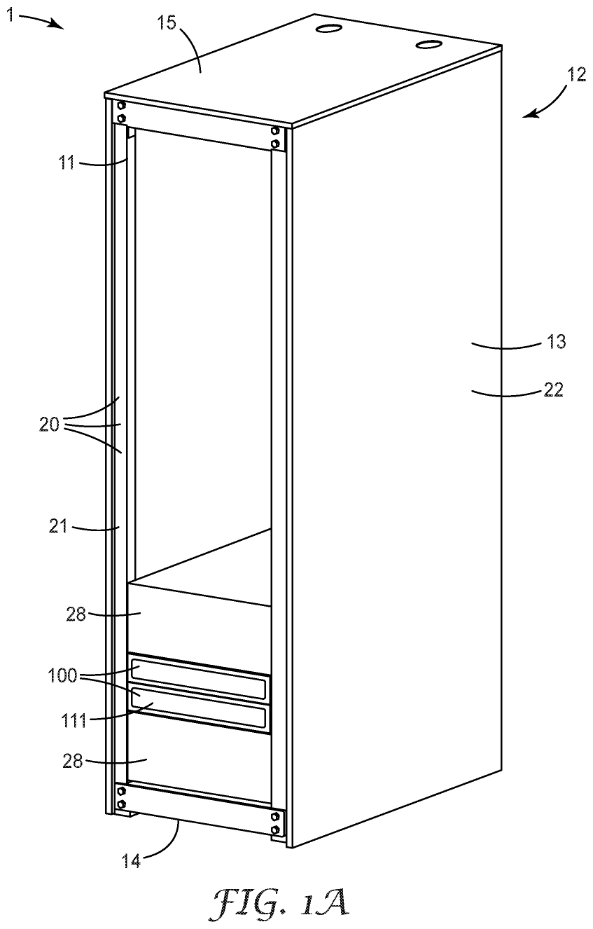

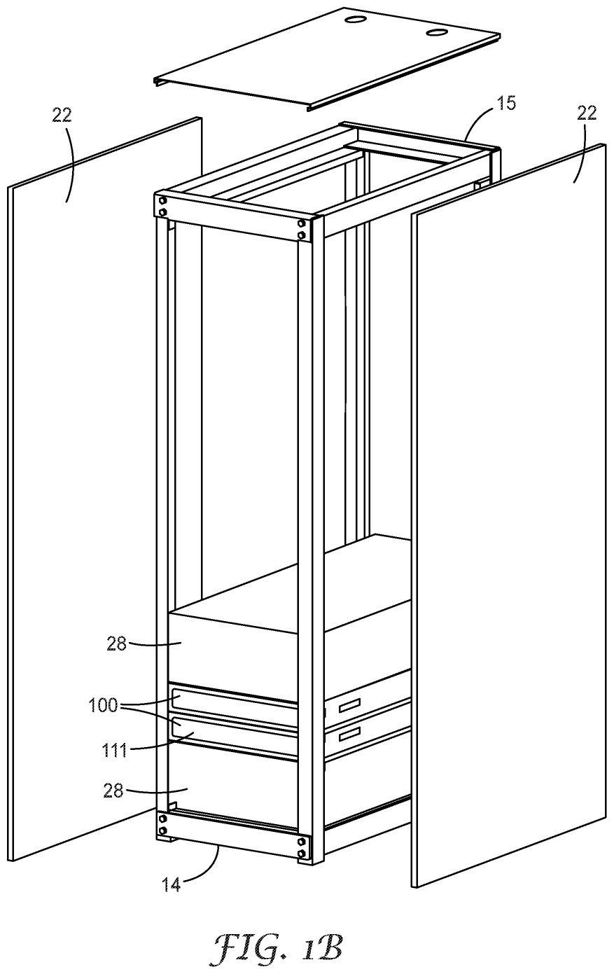

FIG. 1A illustrates schematically an electronics rack 1 and computer equipment 28 and sound-absorbing blanking panels 100 mounted onto the rack 1. The sound-absorbing blanking panels 100 may occupy otherwise vacant positions on the rack 1 that do not have electronic equipment mounted onto them. FIG. 1B is an exploded view of the rack 1.

The electronics rack 1 may be, for example, a server rack constructed to house hard disk drives and/or other electronics. The electronics rack 1 has vertical mounting rails 21, and a plurality of mounting positions 20 on the mounting rails 21. Electronic equipment 28, such as hard disk drives, may be mounted into the mounting positions 20.

The sound-absorbing blanking panels 100 may be mounted onto the mounting rails 21 of the rack 1. The sound-absorbing blanking panel 100 may occupy the entire mounting position 20 or multiple adjacent mounting positions 20. According to an embodiment, when the sound-absorbing blanking panel 100 is mounted onto the rack 1, a front panel 111 of the sound-absorbing blanking panel 100 at least partially covers the front of at least one mounting position 20 of the rack 1. In some embodiments, the sound-absorbing blanking panel 100 fully covers the front 11 of at least one mounting position 20 of the rack 1. The sound-absorbing blanking panels 100 may extend at least part of the way or all the way from the front 11 of the rack 1 to the back 12 of the rack 1.

The electronics rack 1 may be mounted with one or more sound-absorbing blanking panels 100. For example, the electronics rack 1 may be mounted with 1 or more, 2 or more, 3 or more, 4 or more, 5 or more, etc., sound-absorbing blanking panels 100, up to the number of vacant mounting positions 20 on the electronics rack 1. In some cases it may be desirable to insert a sound-absorbing blanking panel 100 between computer equipment in the electronics rack.

The electronics rack 1 may include additional non-sound absorbing blanking panels. The electronics rack 1 may also include additional sound-absorbing panels, such as side, front, back, top, and/or bottom sound-absorbing panels. The electronics rack 1 may also include additional panels that block, direct, or facilitate air flow, such as solid material panels or perforated or mesh panels. In the embodiment shown, both sides 13 of the rack 1 are covered by solid panels 22. The front and/or back may be covered by mesh screen panels to facilitate air flow.

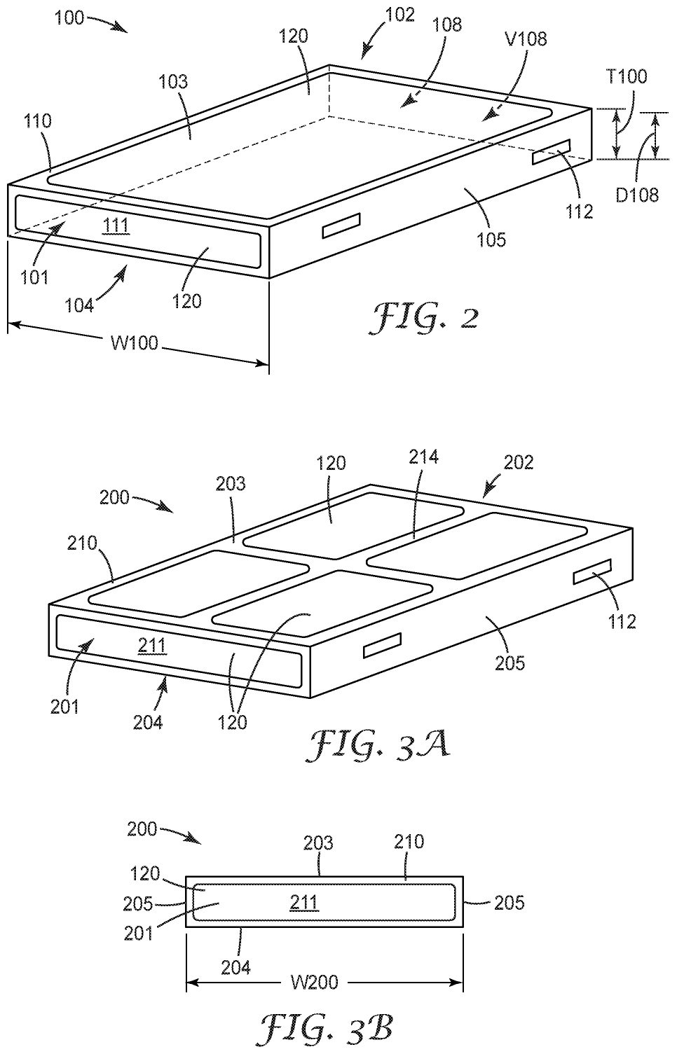

FIG. 2 is a schematic perspective view of a sound-absorbing blanking panel 100 including a sound-absorbing film according to an embodiment. The panel 100 has a frame 110, as well as a front 101, back 102, top 103, bottom 104, and sides 105, that define a cavity 108 inside the panel 100. The front 101, back 102, top 103, bottom 104, and/or sides 105 may be closed (e.g., covered by a material) or open (e.g., not covered by material). The cavity 108 has a depth D108 and volume V108.

The panel 100 has one or more sheets of sound-absorbing film 120 mounted onto the frame 110 and bordering the cavity 108. The one or more sheets of sound-absorbing film 120 may be mounted onto the front 101, back 102, top 103, bottom 104, and/or one or both sides 105 of the frame 110. According to embodiments, the sound-absorbing film 120 may at least partially or substantially cover any of the front 101, back 102, top 103, bottom 104, and/or one or both sides 105. In the exemplary panel 100 shown, the sheets of sound-absorbing film 120 are mounted onto and substantially cover the top 103, bottom 104, and front 101 of the frame 110. The sheets of sound-absorbing film 120 may also be mounted onto the top 103 or bottom 104 only, or the front 101 or back 102 only. The panel 100 may also include additional walls that are not specifically engineered to be sound-absorbing (although the material may absorb some sound). For example, the panel 100 may include a front wall, back wall, side wall, top wall, bottom wall, or a combination thereof, that do not include the sound-absorbing film 120. In some embodiments, either the top 103 or bottom 104 of the panel 100 may be left open such that when the panel 100 is mounted into a vacant position in the rack 1, the adjacent piece of equipment may cover the opening and act as a wall. One or more walls surrounding the cavity 108 and opposite or adjacent the sound-absorbing film 120 may act as a reflective surface for sound waves.

The sound-absorbing film 120 may be supported on the frame 110 internally or externally, or may be unsupported other than by its attachment to the frame 110. In some embodiments, the frame 110 includes a grid, mesh, lattice, or framework extending from side to side or from front to back to provide support for the sound-absorbing film 120.

In some embodiments, the frame 110 forms an electronic enclosure and the sound-absorbing film 120 forms a wall or a side panel of the electronic enclosure. In such embodiments, the sound-absorbing film 120 may be supported by a grid, mesh, lattice, or framework, or may be metalized on one side (e.g., on one of the major surfaces of the sound-absorbing film 120).

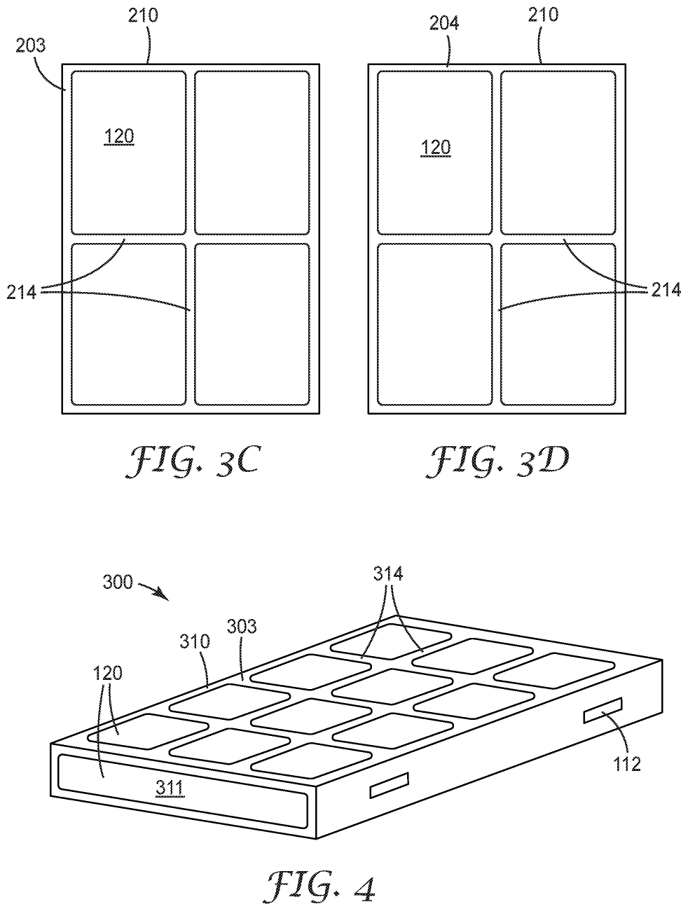

Alternative configurations of the sound-absorbing blanking panel 200, 300 are shown in FIGS. 3A-3C and 4 according to embodiments. The sound-absorbing blanking panels 200, 300 of FIGS. 3A-3C and 4 are otherwise similar to the sound-absorbing blanking panel 100 of FIG. 2 except that the frame 210, 310 provides a grid 214, 314 that supports the sound-absorbing film 120.

FIG. 3A is a perspective view of a sound-absorbing blanking panel 200 with a front 201, back 202, top 203, bottom 204, and sides 205. The panel 200 has one or more sheets of sound-absorbing film 120 mounted onto the frame 210. The one or more sheets of sound-absorbing film 120 may be mounted onto the front 201, back 202, top 203, bottom 204, and/or one or both sides 205 of the frame 210. In the exemplary panel 200 shown, the sheets of sound-absorbing film 120 are mounted onto and substantially cover the top 103 and the bottom 104 of the panel 200 and are supported by the grid 214 formed by the frame 200. A top view of the panel is shown in FIG. 3C and a bottom view in FIG. 3D. The sound-absorbing film 120 is also mounted at the front 201 of the frame 210, as shown in the front view in FIG. 3B.

FIG. 4 depicts another embodiment of the sound-absorbing blanking panel 300 with an alternative grid configuration to support the sound-absorbing film 120. In the embodiment shown, the frame 310 includes a grid 314 at least on the top side 303 of the panel 300. The frame 310 may also include a grid 314 at the bottom, front, back, and/or sides of the panel 300.

Referring now to the embodiments of the sound-absorbing blanking panel 100, 200, 300 generally, the frame 110 may include one or more mounting elements 112 that facilitate mounting and attachment of the panel 100 onto the rack 1. In some embodiments, the frame 110 includes one or more mounting elements 112 that facilitate tool-less mounting, attachment, unmounting, and detachment of the panel 100. In some embodiments the frame 110 includes mounting elements that mate with non-sound absorbing blanking panels such as HOTLOK® panels available from Racksolutions.com in Greenville, Tex.

The sound-absorbing blanking panel 100 may be constructed to have any desired size to accommodate one or more vacant mounting positions 20. The thickness T100 of the panel 100 may be equal to the thickness of the frame extending from the top 103 to the bottom 104, or may be the thickness of the sheet of sound-absorbing material. In some embodiments, the thickness T100 is a suitable thickness to cover a vacant position of 1U or greater, 2U or greater, 3U or greater, 4U or greater, up to the size of the vacant position on the rack 1. The sound-absorbing blanking panel 100 may also be constructed to cover one or more mounting apertures or holes on the mounting rails 21 when installed into the rack 1 to help reduce or prevent mixing of exhaust air with cooling air and to help insure that cooling air is forced or drawn into equipment components.

The sound-absorbing blanking panel 100 has a width W100 that accommodates mounting of the panel 100 onto the rack 1 and may also provide an air seal between the outside and the inside of the rack. The width W100 may be a suitable width for the intended rack, such as from 475 mm to 500 mm, from 476 mm to 495 mm, from 575 mm to 600 mm, or from 578 mm to 590 mm.

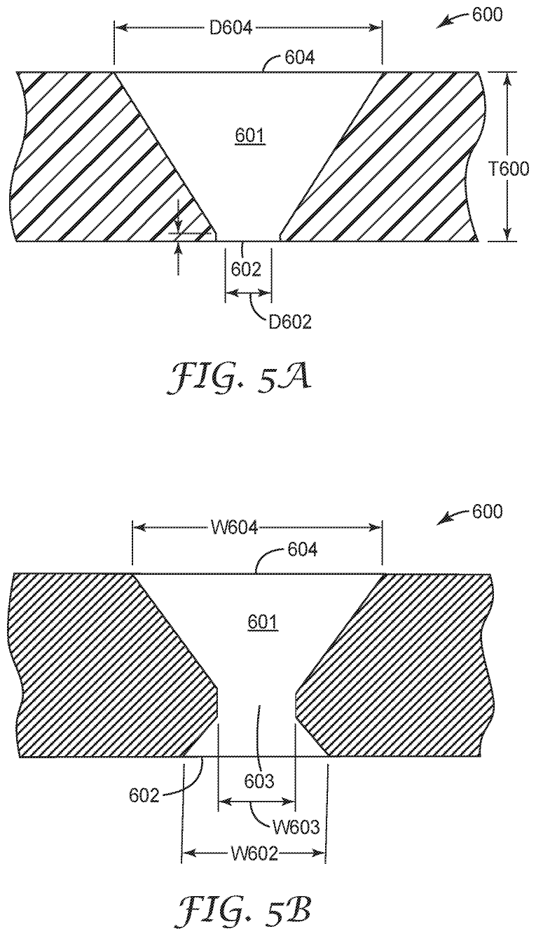

The sound-absorbing film 120 on the sound-absorbing blanking panel 100 may include a suitable film that, when mounted on the panel 100, is capable of absorbing sound. Examples of suitable films include perforated sheets described in U.S. Pat. Nos. 6,617,002 and 6,977,109, both to Wood. The perforated sheet may be a microperforated film with a polymeric film and a plurality of microperforations defined in the film. Cross sectional detail views of microperforated films 600 are shown in FIGS. 5A and 5B according to embodiments. The microperforations 601 may have a first end 604 defining an opening on one side of the film and an opposing second end 602 defining an opening on the opposite side of the film. The microperforations 601 may be funnel-shaped with the first end 604 being a wide end and the second end 602 being a narrow end. The wide and may face an outside of the panel 100 and the narrow end may face the cavity of the panel 100. The narrow end may have a narrowest diameter D602 that is smaller than the thickness T600 of the polymeric film 600. The wide end 604 may have a widest diameter D604 that in some embodiments is wider than the narrowest diameter D602.

FIG. 5B shows an alternative funnel shape that includes a narrow section 603 between the first end 604 and the second end 602. The narrow section 603 has a width W603 that is narrower than either of the width W604 of the first end 604 and the width W602 of the second end 602.

The shape of the opening of the microperforations 601 (e.g., the shape of the opening formed by the first and/or second ends 604, 602) may be circular, square, hexagonal, or any other suitable shape. In some embodiments, microperforations 601 have a substantially circular cross section.

In some embodiments one or more of the shape of the perforations, physical properties of the microperforated film, hole spacing (e.g., pitch), cavity depth, and characteristics of the reflective surface, may be adjusted to adjust (e.g., tune) the absorption bands of the panel. For example, a peak absorption frequency may be increased by increasing the size of the perforations and/or decreasing the depth of the cavity. The opposite adjustments can be used to decrease peak absorption frequency of the panel. The magnitude of the peak is related to the transfer impedance of the perforated film, which can also be manipulated by adjusting the hole depth and perforation pattern.

The perforations of the microperforated film may have a narrowest diameter (e.g., the width at the narrow end or the narrow section) of 30 μm or greater, 40 μm or greater, 50 μm or greater, 60 μm or greater, 70 μm or greater, 80 μm or greater, 90 μm or greater, or 100 μm or greater. The perforations of the microperforated film may have a narrowest diameter of up to 200 μm, up to 150 μm, up to 120 μm, up to 100 μm, up to 90 μm, or up to 80 μm.

The perforations of the microperforated film may have a widest diameter (e.g., the width at the wide end) of 100 μm or greater, 150 μm or greater, 180 μm or greater, 200 μm or greater, 220 μm or greater, 230 μm or greater, 240 μm or greater, or 250 μm or greater. The perforations of the microperforated film may have a widest diameter of up to 1000 μm, up to 800 μm, up to 700 μm, up to 650 μm, up to 600 μm, up to 550 μm, up to 500 μm, up to 450 μm or up to 400 μm.

The perforations of the microperforated film may have a pitch (distance from center to center of adjacent perforations) of 300 μm or greater, 400 μm or greater, 500 μm or greater, or 600 μm or greater. The perforations of the microperforated film may have a pitch of up to 2000 μm, up to 1500 μm, up to 1200 μm, or up to 1000 μm.

The cavity 108 may have a depth D108 that is slightly smaller than the thickness T100 of the sound-absorbing blanking panel 100. For example, the depth D108 may be 2 mm to 10 mm smaller than 1U, 2U, 3U, 4U, etc. The depth D108 may range from 35 mm to 43 mm, or from 75 mm to 86 mm, or from 110 mm to 130 mm, or from 140 mm to 174 mm.

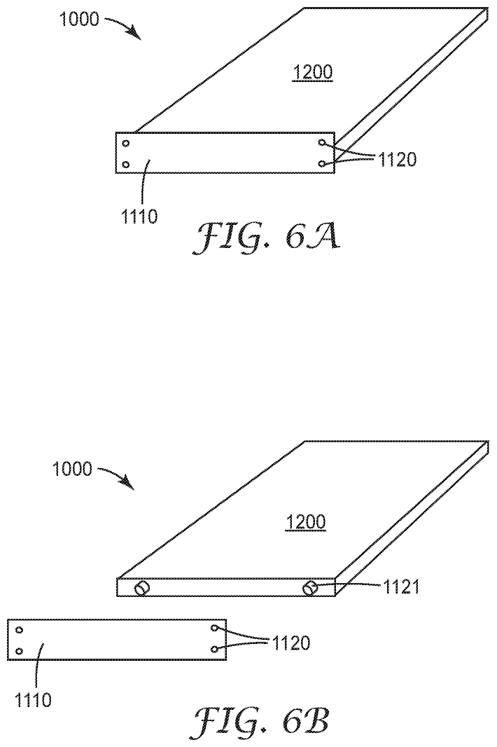

In some embodiments, the sound-absorbing blanking panel 1000 includes a sheet of acoustic-absorbing material 1200, as shown in FIGS. 6A and 6B. The sheet of acoustic-absorbing material 1200 may be mounted (or may be mountable) onto a front panel 1110. The sound-absorbing blanking panel 1000 may be mounted onto the mounting rails 21 of the rack 1.

The front panel 1110 may form a part of (e.g., an integral part of or a part that is removably or permanently attached to) the sound-absorbing blanking panel 1000 or may be a separate piece that is attached to the sheet of acoustic-absorbing material 1200 before or after mounting the sound-absorbing blanking panel 1000 onto the rack 1.

The sound-absorbing blanking panel 1000 may include a frame that supports the sheet of acoustic-absorbing material 1200 as described above. Alternatively, the sheet of acoustic-absorbing material 1200 may be made of a material with sufficient rigidity that the sheet is self-supporting and does not need a frame for support. In such embodiments, the sound-absorbing blanking panel 1000 may be free of a frame.

The sound-absorbing blanking panel 1000 may include one or more mounting elements 1120 that facilitate tool-less mounting, attachment, unmounting, and detachment of the panel 1000. The one or more mounting elements 1120 may be on the sheet of acoustic-absorbing material 1200 or on the front panel 1110. In some embodiments, the sheet of acoustic-absorbing material 1200 includes mounting elements 1121 that facilitate removable attachment of the sheet of acoustic-absorbing material 1200 to the front panel 1110 (e.g., a non-sound absorbing blanking panel such as HOTLOK® panels available from Racksolutions.com in Greenville, Tex.), and the front panel 1110 includes mounting elements that facilitate removable attachment of the front panel 1110 to the rack 1.

The front panel 1110 may be sized to fully cover the front of at least one mounting position 20 of the rack 1. The sheet of acoustic-absorbing material 1200 may extend at least part of the way or all the way from the front 11 of the rack 1 to the back 12 of the rack 1.

In one embodiment, the sound-absorbing blanking panel 100 includes a sheet of acoustic-absorbing material 1200 in place of or in addition to the sound-absorbing film 120.

Examples of suitable materials for preparing a sheet of acoustic-absorbing material 1200 are disclosed in published application WO2018034949 to Jonza et al. Jonza discloses acoustic panels with a layered structure including first and second layers and a honeycomb-like core between the first and second layers.

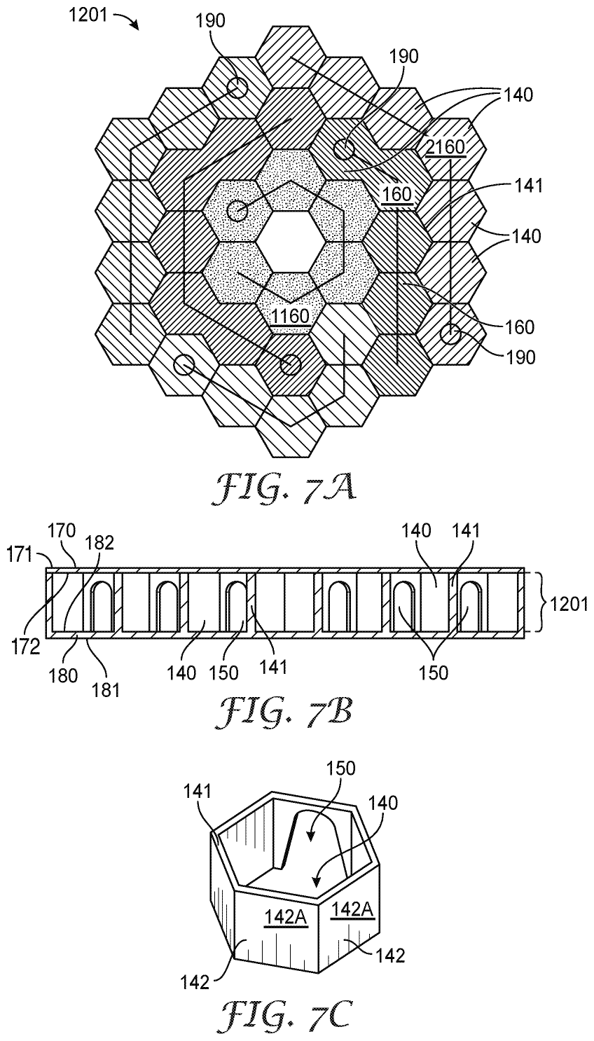

The sheet of acoustic-absorbing material 1200 may include a panel with a layered structure and a core having a honeycomb structure as shown in FIGS. 7A-7C. The layered structure may include planar first and second layers 170, 180 and a core 1201 disposed between the first and second layers. The core may include a plurality of walls 141 extending between the first and second layers 170, 180, dividing the space between the first and second layers 170, 180 into series 160 of interconnected cells 140. The cells 140 are interconnected via openings 150 in at least some of the walls 141. The series 160 of interconnected cells 140 are indicated schematically in FIG. 7A with a line connecting the cells within each series. Also shown are second, third, and subsequent series 1160, 2160 of cells. Each series 160, 1160, 2160, etc. of cells may independently include any suitable number of cells 140, such as 1 or more, 2 or more, 3 or more, 4 or more, 5 or more, 6 or more, or 7 or more cells 140. Each series 160, 1160, 2160, etc. may include up to 40, up to 30, up to 25, up to 20, up to 15, or up to 10 cells. Generally, the number of series in a given panel 100 is not limited and will depend on the size of the panel and the number and size of cells in each series. Typically, a panel 1200 includes a plurality of series 160 that cover the area between the first and second layers 170, 180.

Some or all of the series 160 of interconnected cells 140 may be in fluid communication with the outside environment via one or more holes 190 in the first and/or second layers 170, 180. Each of the first and second layers 170, 180 has outer surfaces 171, 181 facing the outside of the sheet, and inner surfaces 172, 182 facing the core. According to an embodiment, the first layer and/or the second layer 170, 180 includes one or more openings 190 connecting the cells 140 within the core to the outside environment. In some embodiments, the second layer 180 is free of any openings connecting the cells within the core to the outside environment.

In the embodiment shown in FIGS. 7A-7C, each cell wall 141 has a plurality of sides 142. Cell wall side 142 has area 142A. An opening 150 in cell wall 141 a has area 150A. The area 150A of the opening 150 may be at least 50%, at least 55%, at least 60%, at least 65%, at least 70%, or at least 80% of the area 142A of the side 142.

The arrangement shown in FIGS. 7A-7C is only exemplary, as the cells may have a non-hexagonal shape and be arranged in different patterns. The term “honeycomb structure” is used here generally to refer to the layered panels with a multi-cell core but is not limited to the hexagonal shape of the cells. The cells 140 may have a regular geometric shape, such as a polygonal shape. Exemplary shapes include triangles, squares, rectangles, pentagons, hexagons, heptagons, octagons, etc., and combinations thereof. The cells 140 may also have an irregular shape and may include curved and/or straight sections. The series 160 of cells may form a pattern. The pattern may be regular or irregular.

The acoustic characteristics of the panel may be adjusted to accommodate its intended use. In some embodiments, the acoustic characteristics of the panel are adjusted to accommodate use with computers, servers, or server racks. In some embodiments, the acoustic characteristics of the panel are adjusted by selecting properties of the sheet of acoustic-absorbing material 1200. For example, one or more of the panel thickness, cell sizes, size of openings between adjacent cells, size of through holes in the first and/or second layers, and number of connected cells are adjusted to adjust (e.g., tune) the absorption bands of the sheet of acoustic-absorbing material. For example, a peak absorption frequency may be increased by having fewer number of interconnected cells in a series of cells, by decreasing the size of individual cells (e.g., by decreasing the width of the cells or the height of the cells (i.e., the thickness of the core)), by increasing the size of the through holes in the first and/or second layer, by increasing the size of the openings in the walls between adjacent cells, or by decreasing the thickness of the first and/or second layers. The opposite adjustments can be used to decrease peak absorption frequency of the sheet of acoustic-absorbing material.

In some embodiments, the blanking panel may include multiple layers of sound-absorbing materials. The sound-absorbing materials may include one or more types of materials. In one embodiment, the multiple layers of sound-absorbing materials of the panel include at least one layer of a microperforated film. In one embodiment, the multiple layers of sound-absorbing materials of the panel include a sheet of layered multi-cell material. The multiple layers of sound-absorbing materials may also include another type of sound-absorbing material, such as a foam, a non-woven material, or a woven material. In some embodiments, the multiple layers of sound-absorbing materials of the panel include a combination of at least one layer of a microperforated film, layered multi-cell material, a foam, a non-woven material, or a woven material. In one embodiment, the panel includes at least one layer of a microperforated film and a layer of foam. In one embodiment, the panel includes at least one layer of a microperforated film and a layer of non-woven material.

The acoustic characteristics of the blanking panel may be adjusted to accommodate its intended use. According to an embodiment, the acoustic characteristics of the panel are adjusted to accommodate use with computers, servers, or server racks.

The sound-absorbing blanking panel may be constructed to have at least one absorption band at a frequency greater than 100 Hz, greater than 300 Hz, greater than 500 Hz, greater than 800 Hz, greater than 1200 Hz, greater than 1400 Hz, greater than 1600, greater than 1800 Hz, greater than 2000 Hz, or greater than 2100 Hz. The panel may be constructed to have at least one absorption band at a frequency less than 12000 Hz, less than 10000 Hz, less than 8000 Hz, less than 6000 Hz, less than 4000 Hz, less than 3500 Hz, less than 3200 Hz, less than 3000 Hz, less than 2800 Hz, or less than 2600 Hz. The panel may have multiple absorption bands. The absorption bands may be measured using the “Normal Incidence Acoustical Absorption Test” and the “Reverberation Chamber Test” as described in WO2018034949 to Jonza.

In some embodiments, the sound-absorbing blanking panel exhibits an acoustical absorption of at least 50%, at least 55%, at least 60%, at least 65%, at least 70%, at least 75%, or at least 80%. The acoustical absorption of the panels may be measured using the “Normal Incidence Acoustical Absorption Test” and the “Reverberation Chamber Test” as described in WO2018034949 to Jonza.

The sheet of acoustic-absorbing material may have any suitable thickness. For example, the sheet of acoustic-absorbing material may have a thickness from that of a microperforated film, up to the thickness of 1U. The sheet of acoustic-absorbing material may have a thickness of 200 μm or greater, 300 μm or greater, 400 μm or greater, 500 μm or greater, 1 mm or greater, 2 mm or greater, or 5 mm or greater. The thickness of the sheet of acoustic-absorbing material may be up to 44 mm, up to 40 mm, up to 35 mm, up to 30 mm, up to 25 mm, up to 20 mm, up to 15 mm, up to 10 mm, up to 5 mm, up to 2 mm, up to 1500 μm, up to 1200 μm, up to 1000 μm, up to 800 μm, or up to 600 μm.

In some embodiments, the sound-absorbing blanking panel (e.g., the frame or the sheet of acoustic-absorbing material) includes one or more mounting elements 112, 1120 that facilitate tool-less mounting, attachment, unmounting, and detachment of the blanking panel to and from the mounting rails 21. The mounting elements 112, 1120 may include any suitable structure, such as a protrusion, tab, retention hook, alignment peg, clip, or combination thereof, shaped to facilitate releasable mounting and attachment. For example, the frame 110 may include a plurality of mounting elements 112, 1120, where each mounting element is constructed to securely and releasably engage with one of a pair of mounting rails.

In a preferred embodiment, the sound-absorbing blanking panel can be installed into the rack without removing or disturbing existing, already mounted, equipment components above and below the panel location. The mounting elements 112, 1120 of the sound-absorbing blanking panel may be constructed such that the panel may be installed using horizontal movement (e.g., pulling or pushing the panel along a front wall and/or along a side edge), while avoiding vertical movement of the panel.

The sound-absorbing blanking panel may include one or more finger grips that facilitate a user grasping the panel, mounting and installing the panel, and/or unmounting and uninstalling the panel. The finger grips may be constructed so that they allow the user to apply force or pressure to push the panel against the mounting rails to engage the mounting elements 112, 1120 of the sound-absorbing blanking panel with the mounting rails and to thereby install the panel.

The physical characteristics, such as weight, rigidity, compression strength, etc., of the sound-absorbing blanking panel may be adjusted to accommodate its intended use.

The sound-absorbing blanking panel may provide an air seal capable of restricting flow of air. In particular, the sound-absorbing blanking panel may provide an air seal between an outside (e.g., the front side) of the rack and the inside of the rack. For example, an air seal may be provided to restrict air flow between the side walls and/or an adjacent equipment component and/or an adjacent blanking panel. The air seal may be capable of restricting mixing of hot exhaust air with available cooling air within an equipment rack or enclosure.

According to an embodiment, the physical characteristics of the sound-absorbing blanking panel are adjusted to accommodate use with computers, servers, or server racks. For example, the sound-absorbing blanking panel may have sufficient flexural rigidity such that the sound-absorbing blanking panel is self-supporting. That is, sound-absorbing blanking panel may have sufficient rigidity so that the sound-absorbing blanking panel can support its own weight with minimal or no sagging when the sound-absorbing blanking panel is mounted onto the rack and supported at the corners or edges only. In some embodiments, the sound-absorbing blanking panel has a flexural rigidity of at least 5 N·m², or at least 10 N·m² per meter of width.

Advantageously, in some embodiments, the sound-absorbing blanking panel has a thickness in a range from 5 mm to 180 mm, 8 mm to 90 mm, 10 mm to 44 mm, or 15 mm to 25 mm, and exhibits at least one absorption band in the range of 400 Hz to 10,000 Hz, 800 Hz to 5000 Hz, or 900 Hz to 3000 Hz.

Advantageously, in some embodiments, the sound-absorbing blanking panel may be heat-resistant, and may be able to withstand continuous temperatures of 50° C. or greater, 60° C. or greater, or 70° C. or greater without damage or without substantial damage to the panel. Substantial damage is considered to be damage that prevents the panel to be used for its intended purpose, e.g., mounted onto an electronics rack and to absorb sound.

The frame, walls, and/or front panel of the sound-absorbing blanking panel may be prepared from any suitable materials. For example, the frame may be made of polymeric materials, cellulose-based materials, metallic materials, ceramic materials, composite materials (e.g., fiber reinforced, woven or non-woven in a resin matrix), or any combination thereof.

In some embodiments, the frame, walls, and/or front panel of the sound-absorbing blanking panel are manufactured from a cost-effective, light material, such as a cellulose-based material. Exemplary cellulose-based materials include paper, paperboard, cardboard, wood, wood composite materials, and the like. The material may be coated, laminated, and/or reinforced to achieve desirable properties, such as rigidity, resistance to heat, resistance to moisture, etc. In some preferred embodiments, the flame retardant material is halogen free to minimize toxicity. Common halogen-free flame retardants include intumescent materials, phosphorus or nitrogen based flame retardant or inorganic fillers. For example, cardboard products may be treated with a flame retardant solution such as BURN BARRIER™ FPR (available from Fire Retardants, Inc. in Chaska, Minn.). In one embodiment, the frame 110 and/or walls are made from coated or treated cardboard.

The sound-absorbing panel 100 may be prepared from any suitable materials. For example, the frame, walls, front panel and/or the sheet of sound-absorbing material may be independently made of polymeric materials, metallic materials, ceramic materials, composite materials (e.g., fiber reinforced, woven or non-woven in a resin matrix), or any combinations thereof.

Exemplary polymeric materials suitable for manufacturing the sound-absorbing blanking panel (or any part thereof) include polyethylenes, polypropylenes, polyolefins, polyvinylchlorides, polyurethanes, polyesters, polyamides, polystyrene, copolymers thereof, and combinations thereof (including blends). The polymeric materials may be thermosetting by, for example, heat or ultraviolet (UV) radiation, or thermoplastic.

In some embodiments, the sound-absorbing blanking panel (or any part thereof) may be manufactured from or include a high temperature resistant, flame resistant, or flame retardant material. For example, the panel may be manufactured from a high temperature resistant, flame resistant, and/or flame retardant polymer or may include additives that render the material temperature resistant, flame resistant, or flame retardant. Exemplary temperature resistant, flame resistant, or flame retardant polymers include for instance and without limitation, polyamides including PA6, PA66, polybutylene terephthalate (PBT), poly ethylene terephthalate (PET), poly ethylene naphthalate (PEN), polyphenylene sulfide (PPS), Polyether imide (PEI), Polyether sulfone (PES), Polyether ketone (PEK) and Polyether ether ketone (PEEK) and fluoropolymers.

Exemplary additives that may be included in the material of the sound-absorbing blanking panel (or any part thereof) include flame retardants that may be added to the material (e.g., heat resistant polymeric material or other polymeric material). Useful flame retardants include for instance and without limitation, inorganics such as alumina trihydrate (ATH), huntite and hydromagnesite, various hydrates, phosphorus, boron compounds, antimony trioxide and pentoxide and sodium antimonate; halogenated compounds such as organochlorines including chlorendic acid derivatives and chlorinated paraffins; organobromines such as decabromodiphenyl ether (decaBDE), decabromodiphenyl ethane, polymeric brominated compounds, brominated carbonate oligomers (BCOs), brominated epoxy oligomers (BEOs), tetrabromophthalic anyhydride, tetrabromobisphenol A (TBBPA) and hexabromocyclododecane (HBCD); organophosphates such as triphenyl phosphate (TPP), resorcinol bis(diphenylphosphate) (RDP), bisphenol A diphenyl phosphate (BADP), and tricresyl phosphate (TCP); phosphonates such as dimethyl methylphosphonate (DMMP); and phosphinates such as aluminium diethyl phosphinate; compounds containing both phosphorus and a halogen such as tris(2,3-dibromopropyl) phosphate(brominated tris) and chlorinated organophosphates such as tris(1,3-dichloro-2-propyl)phosphate (chlorinated tris or TDCPP) and tetrakis(2-chlorethyl)-dichloroisopentyldiphosphate.

Exemplary metallic materials suitable for manufacturing the sound-absorbing blanking panel (or any part thereof) include aluminum, steel, nickel, copper, brass, bronze, and alloys thereof.

Exemplary ceramic (including glass, glass-ceramic, and crystalline ceramic) materials suitable for manufacturing the sound-absorbing blanking panel (or any part thereof) include oxides, nitrides, and carbides.

Exemplary fiber containing materials suitable for manufacturing the sound-absorbing blanking panel (or any part thereof) include fibers such as cellulose, carbon, thermoplastic fibers (polyamide, polyester, and aramid, polyolefin), steel, and glass.

In some embodiments, materials for panels described herein may be in the form of multilayers or laminates. In some embodiments, the frame, walls, front panel and/or the sheet of sound-absorbing material of the sound-absorbing blanking panel have a single material composition. Such embodiments are desirable to enhance recyclability. The sound-absorbing blanking panel may be constructed from parts or may be partially or fully integral such that some or all of the parts are integrally formed.

Optionally materials for panels described herein may also include fillers, colorants, plasticizers, dyes, etc., as may be applicable to the particular type of material.

The frame, a front panel, a top wall, a bottom wall, and/or side walls of the sound-absorbing blanking panel may have a construction (e.g., materials and/or configuration) that allows for portions of the sound-absorbing blanking panel to deflect when the blanking panel is inserted in the rack 1 for installation. In an alternative embodiment, the sound-absorbing blanking panel includes a relatively rigid frame and/or top or bottom walls. The sound-absorbing blanking panel may include elements along its edge portions that form an interface between the blanking panel and adjacent panels and/or equipment components when the blanking panel is installed. For example, the sound-absorbing blanking panel may include a seal, e.g., a gasket-type or O-ring type, disposed along an edge of the panel that forms an interface between the panel and a surface of an adjacent panel or component to help to create an air seal.

The sound-absorbing film 120 may be made from any suitable material. In some embodiments, the sound-absorbing film 120 includes a polymeric film. Suitable polymeric materials include polyolefins, polyesters, nylons, polyurethanes, polycarbonates, polysulfones, polypropylenes, polyvinylchlorides, and combinations thereof. Copolymers and blends may also be used. In one embodiment, the sound-absorbing film 120 is made from polypropylene, nylon, or a combination thereof. The polymeric material may include additives to adjust the sound absorption properties of the film as well as other characteristics of the film, such as color, printability, adherability, smoke generation resistance, heat/flame retardance, bending stiffness, surface density etc. Examples of additives include plasticizers, barium carbonate, barium sulfate, calcium carbonate lead, quartz, clay, carbon black, fumed silica, glass fibers, various mineral fillers, and the like.

The sheet of sound-absorbing material may be attached to the frame 110 of the sound-absorbing blanking panel 100 or to a front panel by any suitable method. In some embodiments, a sheet of sound-absorbing material is attached to the frame 110 or to a front panel by an adhesive. Pressure sensitive or structural adhesives may be used depending on the desired properties of the finished article. Examples of suitable adhesives include acrylic-based and epoxy-based adhesives. The adhesives may by activated by radiation, such as including ultraviolet, visible, infrared, gamma, or e-beam, or by heating to effect curing. Contact pressure may be sufficient for the pressure sensitive adhesives. In other embodiments, the sheet of sound-absorbing material is attached to the frame 110 or to a front panel by a fastener, such as a screw, rivet, staple, or the like. A combination of fastening mechanisms (e.g., adhesive and fastener) may also be used.

Any suitable method may be used to make the frame 110 of the sound-absorbing blanking panel 100. For example, the frame 110 may be prepared by any known methods, such as molding, extruding, or 3-D printing. In embodiments where the frame 110 has a cardboard construction, the frame 110 may be made by cutting a blank from suitable cardboard, and by folding and/or adhering the blank to form the frame 110.

The sound-absorbing blanking panel 100 may exhibit indicia, such as images or alphanumeric characters. In some embodiments, the indicia includes the mark or label of a trademark or copyrighted material, including a registered trademark or registered copyright as defined under any of the countries, territories, etc., of the world (including the United States). In some embodiments, the indicia is on at least one of the first major surface of the first layer or the second major surface of the second layer.

### EXAMPLES

These examples are merely for illustrative purposes only and are not meant to be limiting on the scope of the appended claims. All parts, percentages, ratios, etc. in the examples and the rest of the specification are by weight, unless noted otherwise. The following abbreviations are used here: m/min=meters per minute; mm=millimeters; cm=centimeters; μm=micrometers; m=meters. 1U is a commonly used unit of measure in the server/computer industry and is equivalent to 1.75 inches (4.45 cm).

Acoustic panels were prepared using various methods as described below.

TABLE 1
Materials.

| Abbreviation | Description |
|---|---|
| TK-2562 | THINSULATE ™ TK Acoustic Insulation consisting of Thinsulate core and |
| | white scrim on both sides. Uncompressed thickness approximately 50 mm. |
| | Available from Aearo Technologies LLC in Indianapolis, Indiana. |
| R-803 | Foam elastomer foil composite (R-803-25-10-100 SM). Uncompressed |
| | thickness approximately 36 mm. Available from Aearo Technologies LLC |
| | in, Indianapolis, Indiana. |
| Thinsulate | High temperature Acoustic Insulation consisting of Thinsulate core and |
| HT | black, chemically resistant scrim on one side. Uncompressed thickness |
| | approximately 25 mm. Available from 3M Company in St. Paul. Minnesota |

### Preparatory Example 1, Honeycomb

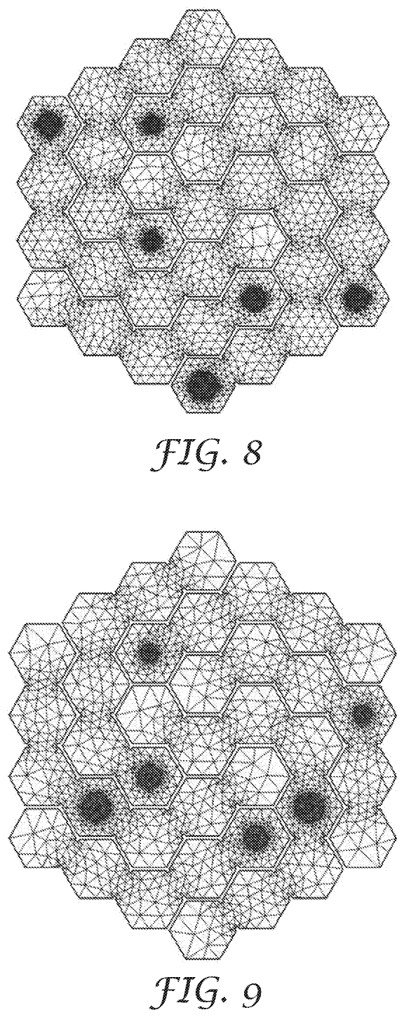

A flat polypropylene (PP) honeycomb panel was prepared according to Example 10 of published application WO2018034949 prior any thermoforming. The honeycomb panel had a 0.5 mm thick PP top skin and bottom skin, and a core with 11.5 mm hexagonal cells and interconnecting passageways connecting cells into series of cells having between 5 and 8 cells per series. Holes were drilled into one of the skins in the same pattern as in the Example (Example 10 of WO2018034949). The prepared panel is referred to as AAH-1 here. The positioning and size of holes are shown in TABLE 2 and in FIG. 8.

TABLE 2
Hole Positioning and Size in AAH-1.

| Series | Hole size and position |
|---|---|
| 5-cell (upper right) | 3 mm hole in end cell |
| 5-cell (lower left) | 4 mm hole in end cell |
| 6-cell (upper left) | 3 mm hole in end cell |
| 6-cell (right side) | 4 mm hole in end cell |
| 7-cell (left side) | 4 mm hole in end cell |
| 8-cell (lower right) | 5 mm hole in end cell |

Another panel was prepared using the same method (Example 10 of WO2018034949) but holes were drilled at different locations and were of different sizes. The panel is referred to as AAH-2. The positioning and size of holes are shown in TABLE 3 and in FIG. 9. The outer dimensions of both panels were 17¼ inch×29 inch (44 cm×74 cm).

TABLE 3
Hole Positioning and Size in AAH-2.

| Series | Hole size and position |
|---|---|
| 5-cell (upper right) | 3 mm hole in end cell |
| 5-cell (lower left) | 4 mm hole in end cell |
| 6-cell (upper left) | 4 mm hole in end cell |
| 6-cell (right side) | 4 mm hole in one of the middle 2 cells |
| 7-cell (left side) | 5 mm hole in center cell |
| 8-cell (lower right) | 5 mm hole in one of the middle 2 cells |

### Preparatory Example 2, Microperforated Film Panels

Microperforated polymeric (MPP) films were prepared using methods described WO 2011/081894. The samples were extruded and embossed with a square array of holes in polypropylene. A flame treatment process was used to perforate the skin side of the film. Approximate dimensions of the perforations for each sample are given in Table 4.

TABLE 4
Physical Characteristics of Microperforated Acoustic Panels.

| | Minimum | | | | |
|---|---|---|---|---|---|
| | Hole | Hole | Film | Exposed | |
| | Opening | Pitch | Thickness | MPP Film | Sample |
| Sample ID | (μm) | (μm) | (μm) | Area (m²) | Numbers |
| MPP-600 | 66 | 530 | 340 | 0.22 | 3, 6 |
| MPP-1200 | 72 | 870 | 375 | 0.19 | 4, 7 |
| MPP-2000 | 75 | 1090 | 333 | 0.22 | 5, 8 |

Strips of the MPP films were sandwiched between frames of 17¼ inch×29 inch×¼ inch (44 cm×74 cm×0.6 cm) thick corrugated cardboard and secured using double sided adhesive tape. Depending on the width of the film, the panels had either 4 or 6 exposed apertures where the microperforated film was visible.

A cardboard grid was assembled to be used in combination with the MPP panels. The outside dimensions of the grid were 17¼ inch×29 inch×1.25 inch (44 cm×74 cm×3.2 cm) with eight, evenly sized apertures. The grid was made from ¼ inch thick corrugated cardboard and adhesive tape. The total thickness of the microperforated acoustic panel plus the grid was approximately 1.75″ (4.45 cm) or 1U to match typical server rack configurations.

### TEST METHODS

### Method 1: Insertion Loss with Internal Sound Source

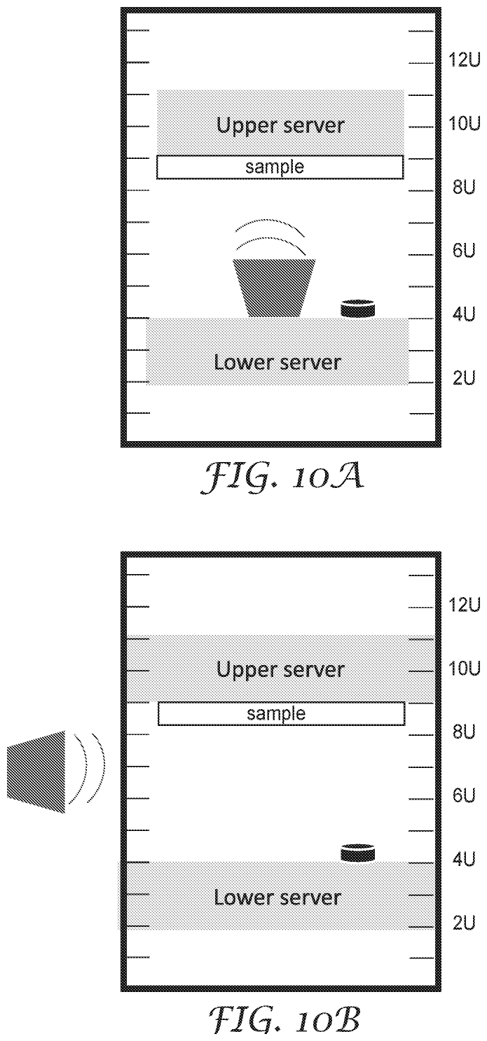

The effect of the acoustic panel on sound pressure levels within an example server rack were measured as follows. A small 12U (19″×31″×23.45″) server rack with closed sides (RackSolutions.com, Greenville, Tex.) was outfitted with two, 2U servers (Hewlett Packard). The servers were secured at the 2U and 9U positions as measured from the bottom of the rack using fixed rails. A set of 1U rails was mounted at the 8U position, directly below the upper server to support the acoustic panel. On the front side of the rack, levels which did not contain either sample acoustic panel or servers, were outfitted with 1U blanking panels (HOTLOK® 1U panels, Racksolutions.com, Greenville, Tex.). A 6 in diameter Harmon Kardon model 320-001/01 speaker was attached to a foam support and then secured to the lid of the lower server. The purpose of the foam is to isolate the speaker mechanical vibrations from the server structure. A schematic of the test set-up is shown in FIG. 10A.

To minimize the effect of background noise, the entire rack assembly was placed inside a small audiometric testing room, model CL-15A built by Eckel Noise Control Technologies. Calibrated multi-field ¼ inch microphones, type 4961 (Brüel & Kjaer, Denmark) were placed in various locations inside the rack: (1) on a foam block next to the speaker; (2) inside the fan cavity of the upper server and the lid closed. Microphone data was collected and analyzed using a Brüel & Kjaer Type 3160-A-042 data acquisition system and the associated Brüel & Kjaer Pulse LabShop software. The fan cavity is immediately adjacent to the hard disk drive arrays in these servers. This is position is expected to be a good proxy for the sound pressure levels inside the hard disk drives themselves. In all cases foam supports were used with each microphone to minimize vibrational coupling between the microphone and the surrounding structures. Note that the computer servers were off during these measurements and served only as mass to represent the geometry and sound paths within a sample electronics rack. Pink noise (also known as 1/f noise) was emitted from the speaker in the range of 10 Hz-20 kHz and the sound pressure level vs. frequency measured at locations (1) and (2). The difference in the measured sound pressure level before and after the application of a particular acoustic treatment (panel) is referred to as the insertion loss.

### Method 2: Insertion Loss with External Sound Source

The insertion loss with a sound source external to the rack was measured using the same equipment and set up as described above. The only difference was that the speaker was removed from the rack and set on a mount inside the acoustic testing room but outside the rack, as indicated in the schematic of the test set-up shown in FIG. 10B.

### Samples

Samples 1 and 2 were AAH panels prepared according to Preparatory Example 1. The AAH panel was supported by the rails and oriented such that the holes in the panel on the lower side faced down towards the lower server.

Samples 3-8 were MPP panels prepared according to Preparatory Example 2. For samples 3-5, the MPP panel absorber alone was supported by the rails and the insertion loss was measured. Samples 6-8 were supported by a cardboard grid that was placed on top of the MPP panel and divides or segments the acoustic backing space above the MPP. The top of the grid barely touched the metal chassis of the upper server.

Samples 9-12 were supported by a single ¼ inch cardboard support with 6 apertures that was placed on top of the rails and then the acoustic absorber material was placed on top. The outside dimensions of the assembly were kept constant at 17¼ inch×29 inch (44 cm×74 cm). The acoustic absorber material used in samples 9 and 10 was R-803 foam elastomer foil composite. In sample 9, the R-803 was oriented with the foil side facing down toward the speaker. In sample 10, the orientation of the R-803 was reversed as compared to sample 9. The acoustic absorber material used in sample 11 was THINSULATE™ HT oriented with the scrim side up facing the upper server. The acoustic absorber material used in sample 12 was TK-2562, THINSULATE™ TK Acoustic Insulation.

For sample 13, a MPP-1200 panel was combined THINSULATE™ HT and a cardboard frame placed around the outside to make a simple assembly. The construction was tested with the MPP-1200 part on the bottom facing the lower server and the THINSULATE™ HT material on top with the black scrim facing the upper server.

Comparative example C1 was a piece of 17¼ inch×29 inch×¼ inch corrugated cardboard (44 cm×74 cm×0.6 cm) placed at the same location in the rack as all the other examples.

Table 5A shows relative sound pressure in each ⅓ octave band (“⅓ OB”) of interest relative to the same experiment with no acoustic absorber panel present (the insertion loss) measured at microphone 1. Table 5B shows relative sound pressure in each ⅓ octave band (“⅓ OB”) (the insertion loss) measured at microphone 2. The largest insertion loss for both microphones at the sound frequencies bands of interest (bands 18, 21, and 25) was measured for Sample 12. A similar set of experiments was repeated using Test Method 2 with an external source. The results are shown in Tables 6A and 6B.

TABLE 5A
Insertion Loss (dB) Measured at Microphone 1 using Test method 1.

| | Center Freq. | Sample number | | | | | | | | | | | | | |
|---|---|---|---|---|---|---|---|---|---|---|---|---|---|---|---|
| ⅓ OB | (Hz) | 1 | 2 | 3 | 4 | 5 | 6 | 7 | 8 | 9 | 10 | 11 | 12 | 13 | C1 |
| 15 | 500 | −2.4 | −11.8 | −0.3 | −0.3 | −0.9 | −3.5 | −3.3 | −4.4 | 3.4 | 5.3 | −2.7 | −8.5 | −1.5 | −17.9 |
| 16 | 630 | 9.9 | 5.2 | 2.0 | 3.5 | 2.7 | 3.6 | 6.2 | 4.3 | 11.3 | 11.7 | 0.4 | −0.1 | 5.8 | −0.9 |
| 17 | 800 | 16.7 | 4.1 | 9.9 | 13.7 | 14.9 | 16.3 | 20.9 | 21.8 | 10.9 | 9.4 | 3.2 | 9.7 | 20.2 | 10.8 |
| 18 | 1000 | 4.7 | 3.9 | 11.8 | 14.2 | 15.3 | 13.5 | 18.9 | 17.4 | 4.3 | 0.6 | 4.8 | 10.8 | 13.4 | 3.9 |
| 19 | 1250 | −0.5 | 3.6 | 5.3 | 2.7 | 2.3 | 1.9 | 2.4 | 0.5 | −0.7 | −3.8 | 7.5 | 6.1 | 4.7 | −3.0 |
| 20 | 1600 | 0.9 | 7.9 | 7.3 | 6.3 | 5.6 | 7.5 | 6.6 | 5.6 | 11.7 | 8.4 | 14.6 | 16.9 | 12.5 | 7.2 |
| 21 | 2000 | 4.2 | 5.0 | 3.8 | 2.8 | 1.9 | 6.7 | 7.6 | 6.1 | 10.2 | 5.5 | 11.9 | 14.8 | 8.6 | 2.9 |
| 22 | 2500 | 2.5 | 4.6 | 8.8 | 9.0 | 7.3 | 5.5 | 3.8 | 4.4 | 2.8 | 6.3 | 12.5 | 12.0 | 7.9 | 0.8 |
| 23 | 3150 | 5.2 | 0.5 | 8.4 | 7.5 | 8.3 | 10.3 | 9.3 | 10.0 | 4.6 | 3.0 | 10.7 | 12.9 | 6.9 | 0.6 |
| 24 | 4000 | 1.6 | −2.6 | 2.5 | 3.9 | 2.3 | 6.7 | 7.4 | 5.8 | 7.6 | 6.2 | 7.7 | 4.4 | 5.2 | −1.7 |
| 25 | 5000 | 1.6 | 0.2 | 5.9 | 5.6 | 5.2 | 4.7 | 8.5 | 3.8 | 10.3 | 12.0 | 9.0 | 10.4 | 8.6 | 0.9 |
| 26 | 6300 | 3.6 | −1.6 | 8.3 | 9.5 | 6.9 | 9.6 | 10.1 | 7.9 | 3.4 | 3.6 | 4.0 | 6.9 | 8.3 | −3.1 |
| 27 | 8000 | 0.9 | −0.6 | 4.0 | 4.2 | 2.5 | 6.5 | 5.3 | 4.4 | 3.6 | 3.9 | 4.4 | 4.8 | 0.0 | 0.0 |
| 28 | 10000 | −1.1 | −0.8 | 1.3 | 0.8 | 1.1 | 2.8 | 1.3 | 2.2 | 3.5 | 3.8 | 2.5 | 5.0 | 1.4 | 0.7 |
| 29 | 12500 | 0.0 | 1.0 | 5.1 | 4.3 | 2.6 | 3.7 | 2.2 | 1.1 | 4.9 | 5.5 | 5.9 | 6.6 | 5.2 | 1.1 |
| 30 | 16000 | 1.0 | −0.9 | 1.4 | 3.0 | 1.2 | 2.9 | 2.6 | 2.3 | −0.3 | 4.1 | 4.5 | 5.7 | 2.0 | 1.5 |
| 31 | 20000 | 1.4 | −0.5 | 2.7 | 1.3 | 1.0 | 2.1 | 2.6 | 1.6 | −0.4 | 1.5 | 1.0 | 3.9 | 4.6 | −1.1 |

| | | | | | | | | | | | | | | |
|---|---|---|---|---|---|---|---|---|---|---|---|---|---|---|
| Average insertion loss | 2.1 | 1.8 | 6.1 | 6.1 | 5.3 | 6.9 | 7.4 | 6.2 | 5.6 | 4.5 | 8.1 | 9.6 | 7.1 | 0.9 |
| (1-10 kHz) | | | | | | | | | | | | | | |
| Average insertion loss | 2.9 | 1.0 | 5.2 | 5.4 | 4.7 | 5.9 | 6.6 | 5.6 | 5.4 | 5.1 | 6.0 | 7.2 | 6.7 | 0.2 |
| (500-20 kHz) | | | | | | | | | | | | | | |

TABLE 5B
Insertion loss (dB) measured at Microphone 2 using Test Method 1.

| | Center Freq. | Sample number | | | | | | | | | | | | | |
|---|---|---|---|---|---|---|---|---|---|---|---|---|---|---|---|
| ⅓ OB | (Hz) | 1 | 2 | 3 | 4 | 5 | 6 | 7 | 8 | 9 | 10 | 11 | 12 | 13 | C1 |
| 15 | 500 | −14.6 | −11.9 | −1.6 | −2.8 | −5.2 | −7.2 | −8.6 | −8.8 | 7.0 | 7.0 | 5.1 | −5.9 | 2.1 | −10.0 |
| 16 | 630 | 10.3 | 14.4 | 0.6 | 2.1 | 0.5 | 1.6 | 2.4 | 1.7 | 9.3 | 10.0 | 1.0 | 4.4 | 5.9 | 12.3 |
| 17 | 800 | 10.9 | 2.6 | 8.2 | 10.5 | 9.6 | 10.9 | 11.4 | 10.8 | 11.3 | 10.5 | 2.2 | 6.8 | 9.4 | 8.9 |
| 18 | 1000 | 5.7 | 1.6 | 4.9 | 4.5 | 5.1 | 7.1 | 9.5 | 8.8 | 2.1 | 3.4 | 4.3 | 8.0 | 7.7 | 0.8 |
| 19 | 1250 | 5.6 | 3.2 | 1.7 | 0.9 | 1.7 | 1.2 | 3.5 | 5.0 | 2.1 | 2.4 | 3.3 | 6.4 | 4.5 | −1.0 |
| 20 | 1600 | 1.8 | 0.2 | 5.9 | 6.7 | 6.6 | 7.1 | 7.1 | 7.1 | 11.6 | 8.5 | 12.3 | 7.7 | 9.0 | −1.3 |
| 21 | 2000 | 4.7 | 4.1 | 2.5 | 2.3 | 1.7 | 7.7 | 8.5 | 6.1 | 6.5 | 5.0 | 13.8 | 14.9 | 11.6 | 5.6 |
| 22 | 2500 | 6.8 | 2.7 | 12.4 | 13.3 | 11.6 | 10.6 | 12.6 | 11.4 | 3.6 | 8.6 | 7.7 | 6.9 | 7.2 | −1.1 |
| 23 | 3150 | 3.3 | 3.8 | 6.4 | 7.4 | 6.2 | 6.5 | 6.8 | 6.1 | 7.9 | 6.7 | 10.2 | 11.9 | 4.8 | 3.8 |
| 24 | 4000 | 3.0 | 3.6 | 7.9 | 7.3 | 6.1 | 7.3 | 6.4 | 6.1 | 9.9 | 8.6 | 11.7 | 12.8 | 5.7 | 2.7 |
| 25 | 5000 | 4.2 | 3.7 | 3.6 | 4.6 | 3.4 | 6.4 | 8.0 | 4.4 | 9.2 | 8.3 | 10.4 | 7.7 | 5.1 | 0.5 |
| 26 | 6300 | 1.8 | 3.7 | 3.9 | 4.4 | 3.1 | 4.9 | 4.7 | 4.5 | 5.2 | 5.0 | 6.8 | 7.3 | 5.2 | 0.6 |
| 27 | 8000 | 0.6 | 1.5 | 1.6 | 1.8 | 1.3 | 1.6 | 1.8 | 1.5 | 3.1 | 2.8 | 3.3 | 4.4 | 3.0 | 1.0 |
| 28 | 10000 | 1.0 | 1.0 | 1.6 | 2.1 | 1.4 | 1.8 | 2.0 | 1.6 | 2.9 | 3.0 | 3.3 | 4.5 | 3.9 | 0.8 |
| 29 | 12500 | 0.5 | 0.9 | 0.8 | 0.7 | 0.6 | 0.9 | 0.8 | 0.7 | 1.5 | 1.9 | 1.8 | 2.6 | 1.3 | 1.3 |
| 30 | 16000 | 0.0 | 0.3 | 0.4 | 0.3 | 0.3 | 0.4 | 0.3 | 0.4 | 0.4 | 0.5 | 0.5 | 0.7 | 0.4 | 0.4 |
| 31 | 20000 | 0.0 | 0.2 | 0.8 | 0.7 | 0.6 | 0.7 | 0.3 | 0.6 | 0.4 | 0.5 | 0.5 | 1.0 | 1.0 | 0.1 |

| | | | | | | | | | | | | | | |
|---|---|---|---|---|---|---|---|---|---|---|---|---|---|---|
| Average insertion loss | 3.5 | 2.7 | 4.8 | 5.0 | 4.4 | 5.7 | 6.5 | 5.7 | 5.8 | 5.7 | 7.9 | 8.4 | 6.2 | 1.1 |
| (1-10 kHz) | | | | | | | | | | | | | | |
| Average insertion loss | 2.7 | 2.1 | 3.6 | 3.9 | 3.2 | 4.1 | 4.6 | 4.0 | 5.5 | 5.5 | 5.8 | 6.0 | 5.2 | 1.5 |
| (500-20 kHz) | | | | | | | | | | | | | | |

TABLE 6A
Insertion Loss (dB) Measured Using Test Method 2 at Microphone 1.

| | Center Freq. | Sample number | | | | | | | | | | |
|---|---|---|---|---|---|---|---|---|---|---|---|---|
| ⅓ OB | (Hz) | 1 | 2 | 3 | 4 | 5 | 9 | 10 | 11 | 12 | 13 | C1 |
| 15 | 500 | −2.0 | −2.6 | −0.2 | 2.4 | 4.9 | −2.4 | −1.0 | 1.0 | 2.3 | 0.4 | −5.0 |
| 16 | 630 | −1.4 | −2.5 | 0.5 | 3.4 | 2.9 | −0.8 | 0.9 | 2.0 | 3.1 | 2.2 | −2.1 |
| 17 | 800 | 7.1 | 9.0 | 2.2 | −5.4 | −2.7 | 0.8 | 5.3 | 2.9 | 4.6 | 4.4 | 5.6 |
| 18 | 1000 | 1.0 | 4.0 | 1.7 | −1.4 | 1.8 | −1.3 | 5.9 | 3.7 | 6.2 | 2.0 | −0.2 |
| 19 | 1250 | 0.6 | 2.7 | 2.7 | 0.0 | 3.4 | −0.3 | 1.1 | 1.5 | 3.0 | 5.1 | 0.0 |
| 20 | 1600 | 2.2 | 3.0 | 3.4 | 0.5 | 1.3 | 1.3 | 5.6 | 4.3 | 6.1 | 6.0 | 2.5 |
| 21 | 2000 | 0.5 | 0.8 | 0.4 | 1.3 | −2.2 | −0.2 | 1.6 | 3.3 | 4.1 | 2.4 | 2.8 |
| 22 | 2500 | 0.7 | 0.2 | 2.3 | 1.2 | 0.6 | 0.2 | 2.5 | 2.3 | 3.0 | 2.3 | 1.3 |
| 23 | 3150 | 2.0 | 1.7 | 0.5 | 0.0 | 1.5 | −0.3 | 2.5 | 1.3 | 2.0 | 0.1 | −0.8 |
| 24 | 4000 | −0.2 | 0.1 | −0.5 | 0.0 | 0.3 | 0.6 | 2.1 | 1.4 | 2.2 | −1.7 | −1.3 |
| 25 | 5000 | 1.0 | 0.4 | 1.8 | 1.1 | 1.5 | 0.1 | 2.4 | 2.6 | 3.0 | 1.7 | 0.0 |
| 26 | 6300 | 0.1 | −0.5 | 1.9 | 1.4 | 1.4 | 0.7 | 2.3 | 2.8 | 2.6 | 2.7 | 1.0 |
| 27 | 8000 | −0.3 | 0.4 | 1.4 | 0.1 | 0.4 | −0.4 | −0.8 | 1.1 | 1.0 | 1.6 | 0.7 |
| 28 | 10000 | 0.3 | −0.1 | 1.3 | 1.1 | 0.4 | 0.1 | 0.4 | 1.0 | 1.4 | 0.9 | 0.2 |
| 29 | 12500 | −0.2 | −0.2 | 0.1 | −0.4 | −0.3 | 0.3 | −0.3 | −0.3 | 0.0 | −0.9 | −0.6 |
| 30 | 16000 | 0.0 | 0.0 | 0.0 | 0.1 | −0.1 | 0.0 | −0.8 | 0.2 | 0.2 | 0.1 | 0.1 |
| 31 | 20000 | 0.0 | 0.0 | −0.1 | 0.0 | 0.1 | −0.1 | −0.4 | 0.2 | 0.1 | −0.1 | −0.1 |

| | | | | | | | | | | | |
|---|---|---|---|---|---|---|---|---|---|---|---|
| Average insertion loss | 0.7 | 1.2 | 1.5 | 0.5 | 0.9 | 0.0 | 2.3 | 2.3 | 3.1 | 2.1 | 0.6 |
| (1-10 kHz) | | | | | | | | | | | |
| Average insertion loss | 0.7 | 1.0 | 1.1 | 0.3 | 0.9 | −0.1 | 1.7 | 1.8 | 2.6 | 1.7 | 0.2 |
| (500-20 kHz) | | | | | | | | | | | |

TABLE 6B
Insertion Loss (dB) Measured Using Test Method 2 at Microphone 2.

| | Center Freq. | Sample number | | | | | | | | | | |
|---|---|---|---|---|---|---|---|---|---|---|---|---|
| ⅓ OB | (Hz) | 1 | 2 | 3 | 4 | 5 | 9 | 10 | 11 | 12 | 13 | C1 |
| 15 | 500 | −0.5 | −0.6 | −0.3 | 0.1 | −0.3 | −0.2 | 0.0 | 0.1 | 0.7 | −0.6 | −0.2 |
| 16 | 630 | 0.3 | −0.1 | −0.1 | 0.0 | 0.0 | −0.5 | −0.2 | 0.2 | 0.9 | −0.6 | −0.4 |
| 17 | 800 | −0.1 | −0.2 | 0.3 | 0.7 | 0.2 | 1.2 | 0.7 | 0.8 | 1.4 | 0.4 | 0.2 |
| 18 | 1000 | −0.4 | −0.9 | 0.3 | 0.0 | 0.5 | 1.9 | 0.5 | 0.5 | 2.2 | −0.2 | 0.9 |
| 19 | 1250 | −2.0 | −1.9 | −0.5 | −0.8 | −0.7 | 2.8 | 1.7 | 0.6 | 2.2 | 0.7 | −1.7 |
| 20 | 1600 | −1.0 | 0.0 | 0.8 | 0.1 | 0.9 | 0.4 | 0.0 | 0.7 | 0.4 | 0.1 | 0.4 |
| 21 | 2000 | −0.4 | −0.1 | 0.3 | 0.3 | 0.4 | 0.2 | −0.4 | 0.3 | 0.6 | 0.8 | 0.0 |
| 22 | 2500 | 0.0 | 0.1 | −0.1 | 0.3 | −0.2 | 0.1 | 0.2 | 0.1 | 0.5 | −0.2 | −0.7 |
| 23 | 3150 | 0.3 | 0.4 | 0.3 | 0.5 | 0.2 | 0.5 | 0.8 | 0.5 | 0.8 | −0.1 | −0.7 |
| 24 | 4000 | 0.4 | 1.0 | 0.6 | 1.3 | 0.8 | 2.0 | 1.6 | 1.5 | 1.7 | 0.3 | 0.3 |
| 25 | 5000 | 0.1 | 0.4 | 0.1 | 0.5 | 0.2 | 0.3 | 0.8 | 0.5 | 0.6 | 0.0 | 0.1 |
| 26 | 6300 | 0.0 | 0.1 | 0.1 | 0.0 | 0.0 | 0.0 | 0.1 | 0.0 | 0.1 | 0.0 | −0.1 |
| 27 | 8000 | 0.0 | 0.1 | 0.1 | 0.0 | 0.0 | 0.1 | 0.1 | 0.1 | 0.0 | 0.0 | 0.0 |
| 28 | 10000 | 0.0 | 0.0 | 0.0 | 0.1 | −0.1 | 0.1 | 0.1 | 0.1 | 0.1 | 0.0 | 0.0 |
| 29 | 12500 | 0.0 | 0.0 | 0.0 | 0.0 | 0.0 | 0.1 | 0.1 | 0.1 | 0.0 | 0.0 | 0.0 |
| 30 | 16000 | −0.1 | 0.0 | 0.0 | 0.0 | 0.0 | 0.0 | 0.1 | 0.0 | 0.0 | 0.0 | 0.0 |
| 31 | 20000 | 0.0 | 0.0 | 0.0 | 0.0 | 0.0 | 0.0 | 0.0 | 0.0 | 0.0 | 0.0 | 0.0 |

| | | | | | | | | | | | |
|---|---|---|---|---|---|---|---|---|---|---|---|
| Average insertion loss | −0.3 | −0.1 | 0.2 | 0.2 | 0.2 | 0.8 | 0.5 | 0.4 | 0.8 | 0.1 | −0.1 |
| (1-10 kHz) | | | | | | | | | | | |
| Average insertion loss | −0.2 | −0.1 | 0.1 | 0.2 | 0.1 | 0.5 | 0.4 | 0.4 | 0.7 | 0.0 | −0.1 |
| (500-20 kHz) | | | | | | | | | | | |

The measured insertion loss in a given frequency band is a combination of sound absorption and in some cases mode shifting due to changes in the effective size of the cavity. Samples that show both large insertion loss in the bands of interest, for example bands 18, 21 and 25, and positive insertion losses when measured over the broader frequency range, for example 1000 to 10,000 Hz, are the most desirable since they are most likely least sensitive to the dimensions of the cavity. Using test method 1, it was observed that all the acoustic panel samples tested had larger insertion loss in band 18 and from 10-1000 Hz than comparative example C1.

It is further observed that the acoustic panel baffle is more effective at absorbing sound that originates inside the rack than outside it. For sound sources external to the rack, the most effective acoustic panels were Samples 9 and 12 which showed modest sound absorption in band 18 (1000 Hz ⅓ octave band). Negative insertion loss was observed for comparative example C1 in this same band.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. It should be understood that this disclosure is not intended to be unduly limited by the illustrative embodiments and examples set forth herein and that such examples and embodiments are presented by way of example only with the scope of the disclosure intended to be limited only by the claims set forth here.

1. An acoustic-absorbing blanking panel for an electronics rack comprising:
a sheet of acoustic-absorbing material mounted or mountable onto a front panel, the front panel being mountable onto an electronics rack,
the blanking panel exhibiting an absorption band at a frequency between 800 Hz and 12000 Hz.

2. The acoustic-absorbing blanking panel of claim 1, wherein the sheet of acoustic-absorbing material is mounted onto a frame, the frame being mountable onto a server rack.

3. The acoustic-absorbing blanking panel of claim 2, wherein the frame comprises a front panel.

4. The acoustic-absorbing blanking panel of claim 2, wherein the frame defines a cavity and wherein the sheet of acoustic-absorbing material at least partially forms a wall surrounding the cavity.

5. The acoustic-absorbing blanking panel of claim 2, wherein the sheet of acoustic-absorbing material substantially covers a top side of the frame.

6. The acoustic-absorbing blanking panel of claim 2, wherein the sheet of acoustic-absorbing material substantially covers a bottom side of the frame.

7. The acoustic-absorbing blanking panel of claim 1, wherein the sheet of acoustic-absorbing material forms a part of the front panel.

8. The acoustic-absorbing blanking panel of claim 1, wherein the sheet of acoustic-absorbing material comprises an acoustic-absorbing film.

9. The acoustic-absorbing blanking panel of claim 1, wherein the acoustic-absorbing film comprises a polymeric microperforated film.

10. The acoustic-absorbing blanking panel of claim 9, wherein the polymeric microperforated film comprises a plurality of perforations with a narrowest diameter of 30 μm to 200 μm.

11. The acoustic-absorbing blanking panel of claim 9, wherein the polymeric microperforated film comprises a plurality of perforations with a pitch of 300 μm to 2000 μm.

12. The acoustic-absorbing blanking panel of claim 1, wherein the sheet of acoustic-absorbing material comprises non-woven material.

13. The acoustic-absorbing blanking panel of claim 1, wherein the sheet of acoustic-absorbing material comprises a foam.

14. The acoustic-absorbing blanking panel of claim 1, wherein the sheet of acoustic-absorbing material comprises a panel comprising a core having a honeycomb structure.

15. The acoustic-absorbing blanking panel of claim 2, wherein the frame comprises coated cardboard.

16. The acoustic-absorbing blanking panel of claim 1, wherein the acoustic-absorbing blanking panel has an open bottom or an open top.

17. The acoustic-absorbing blanking panel of claim 1 further comprising mounting elements capable of tool-less mounting of the electronics rack.

18. The acoustic-absorbing blanking panel of claim 1 exhibiting an absorption band at a frequency between 2000 Hz and 4000 Hz.

19. An electronics server rack comprising:
a rack comprising mounting rails and constructed to house electronics components;
an acoustic-absorbing blanking panel mounted on the mounting rails, the blanking panel comprising:
a sheet of acoustic-absorbing material mounted onto a front panel, the front panel being mounted onto the rack,
the blanking panel having an absorption band at a frequency between 800 Hz and 12000 Hz.

20. The electronics server rack of claim 19, wherein the acoustic-absorbing blanking panel comprises a frame and the sheet of acoustic-absorbing material is mounted onto the frame.

21-31. (canceled)
